(19) United States
(12) Patent Application Publication
(10) Pub. No.: US 2025/0372938 A1
(43) Pub. Date: Dec. 4, 2025

(54) WAVELENGTH LOCKER AND WAVELENGTH VARIABLE LIGHT SOURCE WITH BUILT-IN WAVELENGTH LOCKER

(71) Applicant: Mitsubishi Electric Corporation, Tokyo (JP)

(72) Inventor: Shuhei YAMAMOTO, Tokyo (JP)

(73) Assignee: Mitsubishi Electric Corporation, Tokyo (JP)

(21) Appl. No.: 18/873,995

(22) PCT Filed: Nov. 2, 2022
(86) PCT No.: PCT/JP2022/041079

§ 371 Date: Dec. 11, 2024

(51) Int. Cl. H01S 3/137; H01S 3/00; H01S 3/04

(52) U.S. Cl. CPC H01S 3/137; H01S 3/0014; H01S 3/0405

(57) ABSTRACT

A beam splitter (3) splits a laser beam (2) to generate first light (5). An etalon (6) allows part of the first light (5) to pass therethrough and reflects remaining part of the first light (5) by an end surface to generate reflected light (7). A reflector (8) reflects the reflected light (7) to a generate second light (9) and causes the second light to enter the etalon (6). Photodetectors (10,11) respectively receive the first light (5) and the second light (9) having passed through the etalon (6). The first light (5) and the second light (9) are different in incident angle to the etalon (6) and are different in optical path length inside the etalon (6).

### FIELD

The present disclosure relates to a wavelength locker and a wavelength variable light source with a built-in wavelength locker.

### BACKGROUND

A wavelength monitor that splits a light beam into two light beams by an optical system, tilts optical axes of the two light beams such that the light beams are relatively shifted with a phase difference of π/2, causes the resultant beams to enter an etalon, and receives the beams by respective photodetectors, and a wavelength variable light source with a built-in wavelength monitor have been proposed (for example, see PTL 1). Thus, two signals can be obtained by a single etalon, and a wavelength variation direction can be recognized with high resolution over a wide band.

### CITATION LIST

### Patent Literature

[PTL 1] JP 2002-202190 A

### SUMMARY OF THE INVENTION

### Problem to be Solved by the Invention

The existing technique, however, has an issue that the optical system splitting the light beam is upsized, and the etalon is also upsized.

The present disclosure has been made to solve the above-described issue, and an object of the present disclosure is to provide a small wavelength locker and a wavelength variable light source with a built-in wavelength locker that can control a wavelength with high accuracy in a wide band.

### Solution to Problem

A wavelength locker according to the present disclosure includes: a beam splitter splitting a laser beam to generate first light; an etalon allowing part of the first light to pass therethrough and reflecting remaining part of the first light by an end surface to generate reflected light; a reflector reflecting the reflected light to a generate second light and causing the second light to enter the etalon; and photodetectors respectively receiving the first light and the second light having passed through the etalon, wherein the first light and the second light are different in incident angle to the etalon and are different in optical path length inside the etalon.

### Advantageous Effects of Invention

In the present disclosure, the first light and the second light different in incident angle to the etalon are used. As a result, the range where the gradient of the transmittance of the etalon to wavelength variation of the light is large is widened, and accordingly, the wavelength locking controllable range of the laser light source can be widened. Thus, even when the finesse of the etalon is increased, the controllable range can be secured. When the finesse is increased, the gradient of the transmittance to the wavelength/temperature can be increased. This makes it possible to control the wavelength with high accuracy. Further, since the second light is obtained by using the reflected light from the etalon, the optical system and the etalon can be downsized.

### BRIEF DESCRIPTION OF THE DRAWINGS

FIG. 1 a diagram illustrating a wavelength variable light source with a built-in wavelength locker according to Embodiment 1.

FIG. 2 is a diagram illustrating frequency dependence of transmittance of a common etalon.

FIG. 3 is a diagram illustrating frequency dependence of a gradient of the transmittance of the common etalon.

FIG. 4 is a diagram illustrating temperature dependence of the transmittance of the common etalon.

FIG. 5 is a diagram illustrating temperature dependence of the transmittance of the common etalon.

FIG. 6 is a diagram illustrating a wavelength locker according to a comparative example.

FIG. 7 is a diagram illustrating frequency dependence of transmittance of the etalon according to the comparative example.

FIG. 8 is a diagram illustrating frequency dependence of a gradient of the transmittance of the etalon according to the comparative example.

FIG. 9 is a diagram illustrating relationship between the incident angle of the light to the etalon and the transmittance of the etalon.

FIG. 10 is a diagram illustrating frequency dependence of transmittance of the etalon according to Embodiment 1.

FIG. 11 is a diagram illustrating frequency dependence of a gradient of the transmittance of the etalon according to Embodiment 1.

FIG. 12 is a diagram illustrating frequency dependence of transmittance of the etalon according to Embodiment 1.

FIG. 13 is a diagram illustrating frequency dependence of a gradient of the transmittance of the etalon according to Embodiment 1.

FIG. 14 is a diagram illustrating relationship between the incident angle of the light to the etalon and the transmittance of the etalon according to Embodiment 1.

FIG. 15 is a diagram illustrating frequency dependence of transmittance of the etalon according to Embodiment 1.

FIG. 16 is a diagram illustrating frequency dependence of a gradient of the transmittance of the etalon according to Embodiment 1.

FIG. 17 is a diagram illustrating frequency dependence of transmittance of the etalon according to Embodiment 1.

FIG. 18 is a diagram illustrating frequency dependence of a gradient of the transmittance of the etalon according to Embodiment 1.

FIG. 19 is a diagram illustrating frequency dependence of transmittance of the etalon according to Embodiment 1.

FIG. 20 is a diagram illustrating a wavelength variable light source with a built-in wavelength locker according to Embodiment 2.

FIG. 21 is a diagram illustrating a wavelength variable light source with a built-in wavelength locker according to Embodiment 3.

### DESCRIPTION OF EMBODIMENTS

A wavelength locker and a wavelength variable light source with a built-in wavelength locker according to the embodiments of the present disclosure will be described with reference to the drawings. The same components will be denoted by the same symbols, and the repeated description thereof may be omitted.

### Embodiment 1

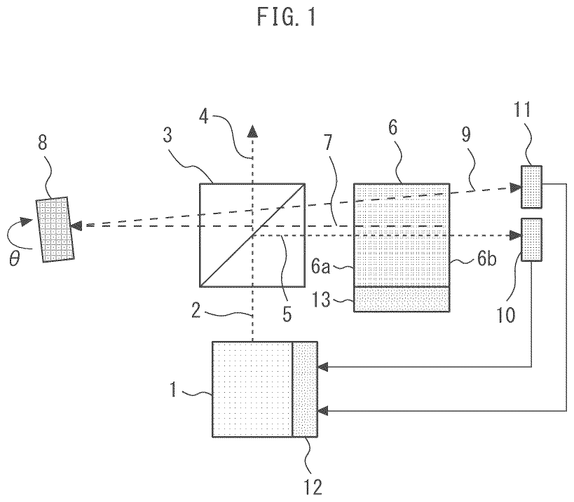

FIG. 1 a diagram illustrating a wavelength variable light source with a built-in wavelength locker according to Embodiment 1. A laser beam 2 is emitted from a laser light source 1. When a current or a voltage of the laser light source 1 is adjusted, an output of the laser light source 1 is controlled.

A beam splitter 3 splits the laser beam 2 into output light 4 and first light 5. The output light 4 passes through the beam splitter 3 and is output to outside. The first light 5 is reflected by the beam splitter 3 in a direction different from a direction of the output light 4. A reflection angle is, for example, 90 degrees, but is not limited thereto.

An etalon 6 includes end surfaces 6a and 6b parallel to each other. The first light 5 enters the etalon 6 from the end surface 6a. The etalon 6 allows part of the first light 5 to pass therethrough, and reflects remaining part of the first light 5 by the end surface 6b to generate reflected light 7.

A high reflection mirror 8 reflects the reflected light 7 at a certain angle to generate second light 9, and causes the second light 9 to enter the etalon 6 again. Photodetectors 10 and 11 are, for example, photodiodes, and respectively receive the first light 5 and the second light 9 having passed through the etalon 6.

The first light 5 and the second light 9 are different in incident angle to the etalon 6 by an angle θ, and are different in optical path length inside the etalon 6. Therefore, the first light 5 and the second light 9j are different in transmission wavelength of the etalon 6 and in clearing temperature of the etalon 6.

A temperature adjustment unit 12 adjusts a temperature of the laser light source 1 based on an output signal of the photodetector 10 or an output signal of the photodetector 11, and performs control to fix an oscillation wavelength of the laser light source 1. The etalon 6 is disposed on a temperature adjustment unit 13. The temperature adjustment unit 13 adjusts a temperature of the etalon 6. Each of the temperature adjustment units 12 and 13 is, for example, a thermoelectric cooler using a Peltier element. A temperature measurement unit measuring the temperature of the etalon 6, such as a thermistor and a thermocouple, is disposed on the etalon 6 or on the temperature adjustment unit 13 near the etalon 6. A temperature measurement unit is also provided on the laser light source 1.

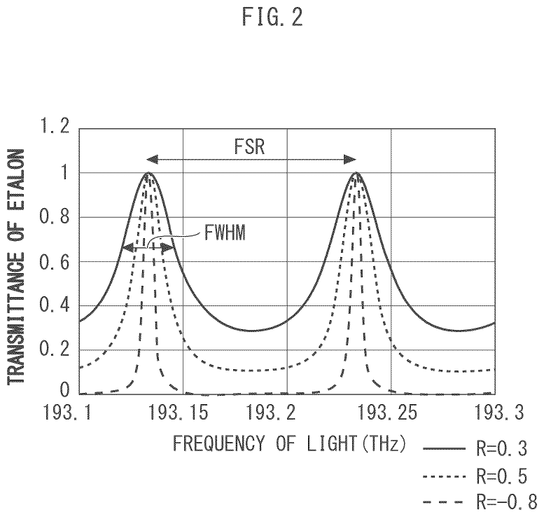

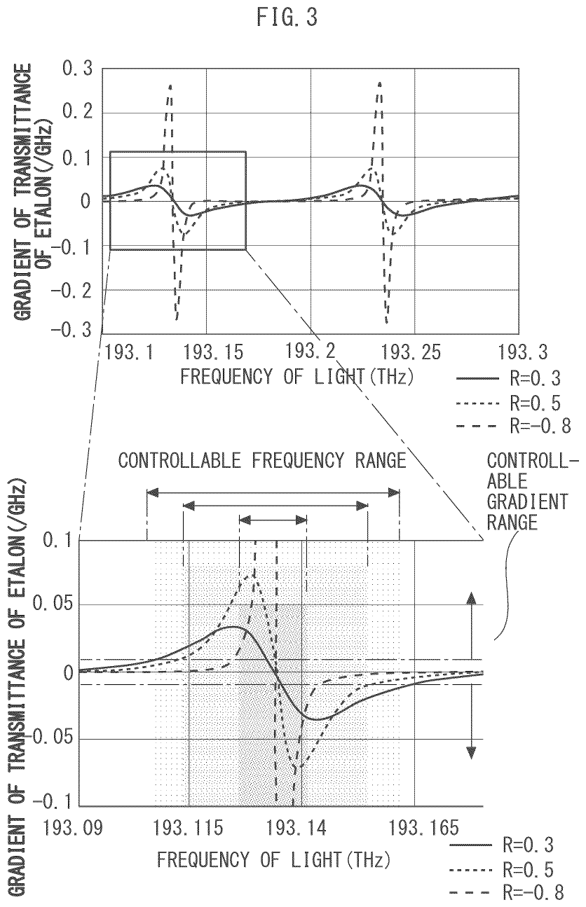

FIG. 2 is a diagram illustrating frequency dependence of transmittance of a common etalon. FIG. 3 is a diagram illustrating frequency dependence of a gradient of the transmittance of the common etalon. FWHM indicates a peak half-value width of a transmission waveform of the etalon. FSR indicates a period of the transmission waveform of the etalon. A finesse F is defined by F=FSR/FWHM.

When reflectance of the etalon is denoted by R, F=πR^{1/2}/(1−R) is established. Therefore, when the reflectance R of the etalon is increased, the finesse can be increased. When the finesse is high, the gradient of the maximum transmittance is increased. Therefore, a current of the photodetector is varied by slight wavelength variation, which makes it possible to control the wavelength with high accuracy. On the other hand, to lock the wavelength, it is necessary to control the wavelength within a region where the gradient of the transmittance to wavelength variation is large. When the finesse is high, the region where the gradient of the transmittance is large is narrow. Thus, the wavelength is easily unlocked.

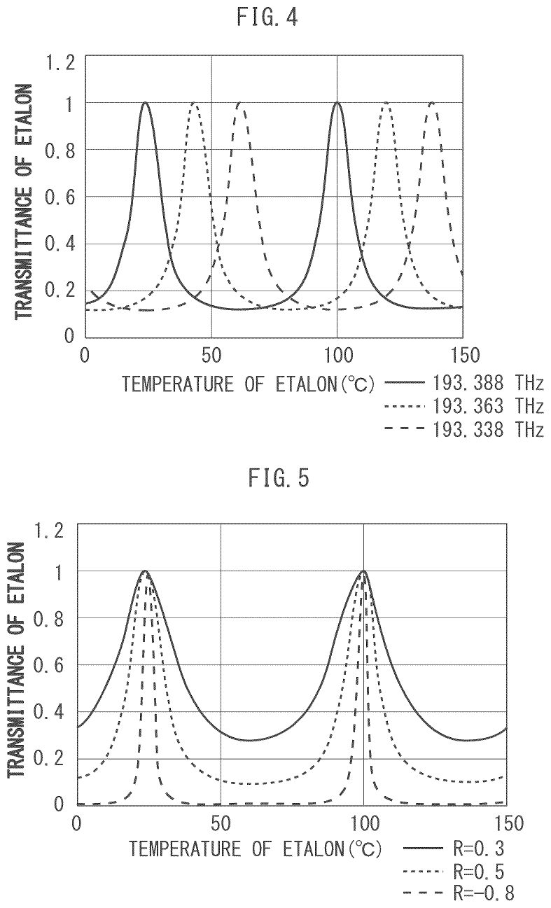

FIG. 4 and FIG. 5 are diagrams each illustrating temperature dependence of the transmittance of the common etalon. FIG. 4 illustrates a case where the finesse is fixed but the frequency of the light is varied. FIG. 5 illustrates a case where the frequency of the light is fixed but the finesse is varied. When the temperature of the etalon is varied, the transmittance of the etalon is varied. When the frequency of the light is varied, a peak position of the transmittance to the temperature of the etalon is changed. Therefore, to lock the wavelength at a desired wavelength, the temperature of the etalon is varied and set to a temperature at which the gradient of the transmittance is large.

However, when the temperature of the etalon is deviated from an ambient environment temperature, large power is necessary to maintain the constant temperature. Therefore, widening of a wavelength locking controllable range and suppression of power consumption for controlling the temperature of the etalon are design items contradicting wavelength control with high accuracy.

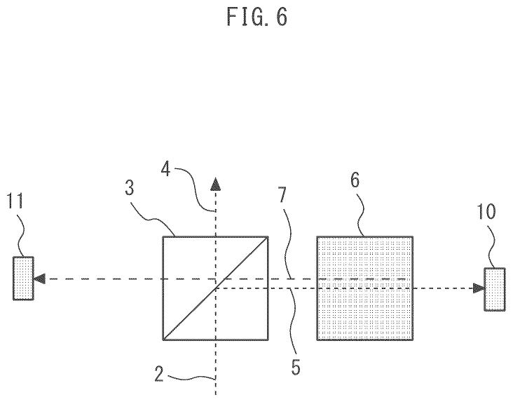

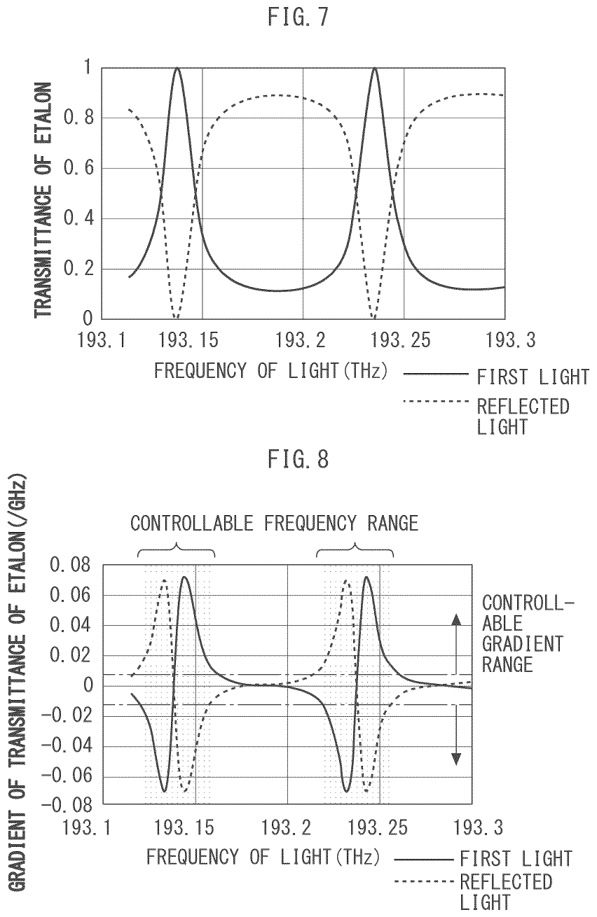

FIG. 6 is a diagram illustrating a wavelength locker according to a comparative example. The photodetector 11 directly receives the reflected light 7 from the etalon 6. FIG. 7 is a diagram illustrating frequency dependence of transmittance of the etalon according to the comparative example. FIG. 8 is a diagram illustrating frequency dependence of a gradient of the transmittance of the etalon according to the comparative example. A positive/negative sign of the gradient of the transmittance of the etalon 6 is inverted between the first light 5 and the reflected light 7. However, the wavelength locking controllable region where the gradient of the transmittance is large is not widened.

In contrast, in the present embodiment, the wavelength locking controllable region where the gradient of the transmittance is large is widened by using the first light 5 and the second light 9 that are different in incident angle to the etalon 6. This is described in detail below.

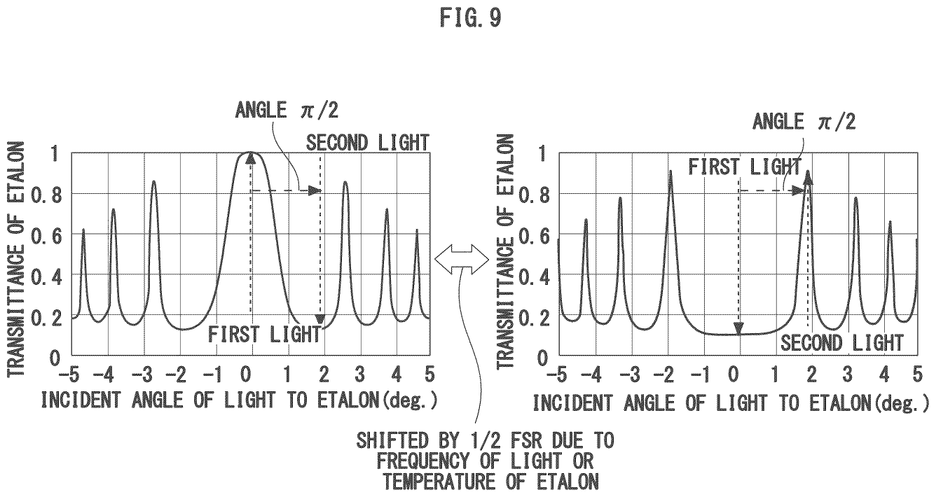

FIG. 9 is a diagram illustrating relationship between the incident angle of the light to the etalon and the transmittance of the etalon. A material of the etalon is synthetic quartz, FRS is 100 GHz, and an angle π/2 is 1.9 degrees. Right data and left data are shifted by ½ FSR due to the frequency of emission light from the laser light source 1 or the temperature of the etalon 6. When an incident angle difference θ between the first light 5 and the second light 9 is set to the angle π/2, characteristics of the etalon 6 to the second light 9 are shifted by a half period from the characteristics of the etalon 6 to the first light 5.

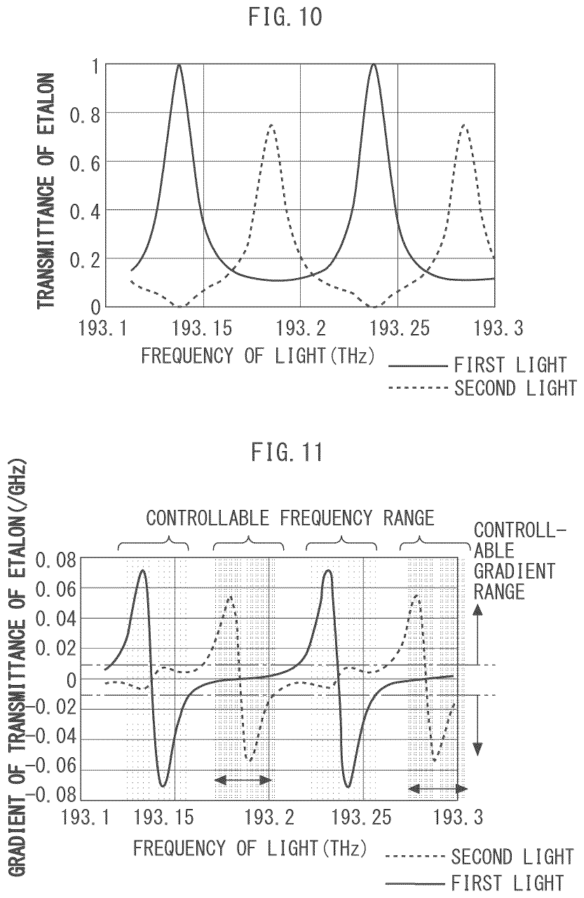

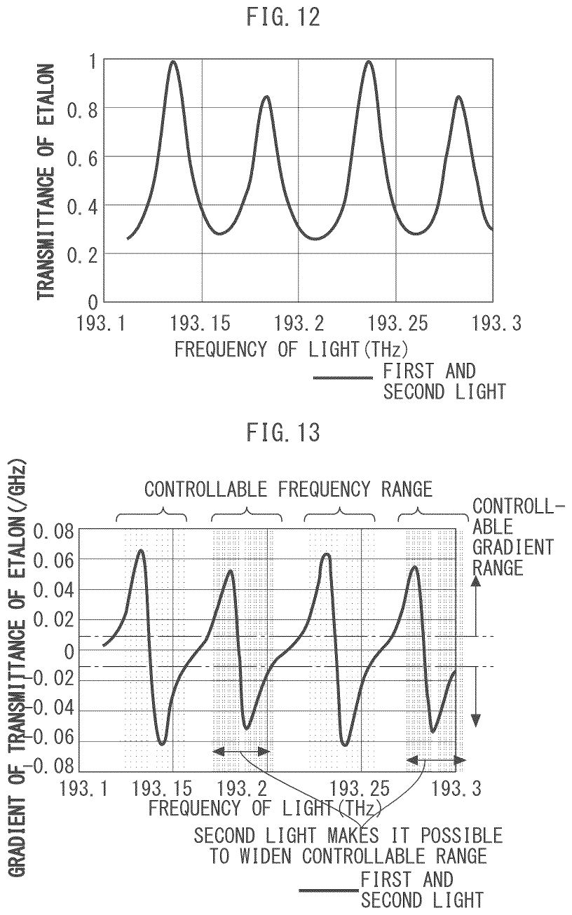

FIG. 10 and FIG. 12 are diagrams each illustrating frequency dependence of transmittance of the etalon according to Embodiment 1. FIG. 11 and FIG. 13 are diagrams each illustrating frequency dependence of a gradient of the transmittance of the etalon according to Embodiment 1. FIG. 10 to FIG. 13 illustrate a case where the incident angle difference θ between the first light 5 and the second light 9 is set to the angle π/2. FIG. 10 and FIG. 11 illustrate a case where the photodetectors 10 and 11 are separated. FIG. 12 and FIG. 13 illustrate a case where light is collectively received by one photodetector. Using not only the first light 5 but also the second light 9 makes it possible to widen the wavelength locking controllable range.

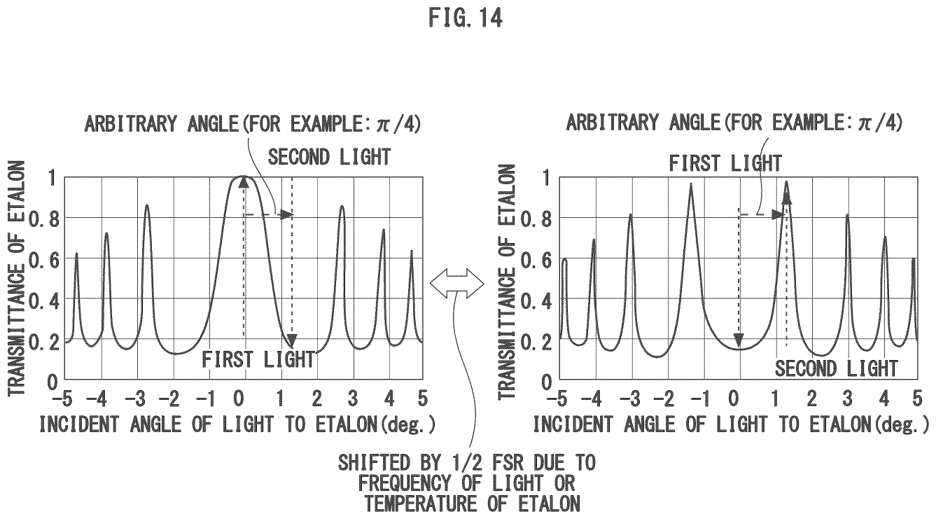

FIG. 14 is a diagram illustrating relationship between the incident angle of the light to the etalon and the transmittance of the etalon according to Embodiment 1. A material of the etalon is synthetic quartz, FRS is 100 GHz, and an angle π/4 is 1.3 degrees. Right data and left data are shifted by ¼ FSR due to the frequency of emission light from the laser light source 1 or the temperature of the etalon 6. When the incident angle difference θ between the first light 5 and the second light 9 is set to the angle π/4, the characteristics of the etalon 6 to the second light 9 are shifted by a ¼ period from the characteristics of the etalon 6 to the first light 5. Adjusting the incident angle difference θ in such a manner makes it possible to obtain the characteristics of the etalon 6 having an optional peak position.

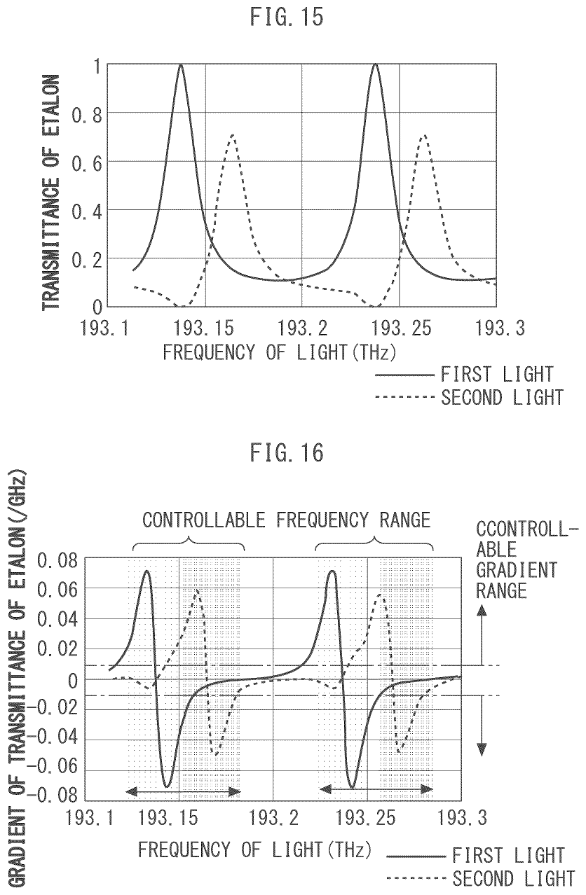

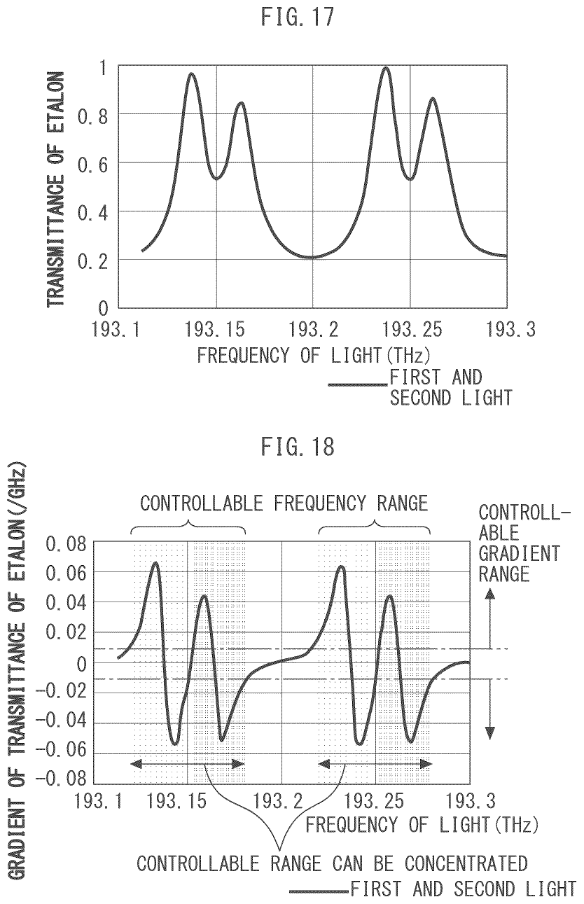

FIG. 15 and FIG. 17 are diagrams each illustrating frequency dependence of transmittance of the etalon according to Embodiment 1. FIG. 16 and FIG. 18 are diagrams each illustrating frequency dependence of a gradient of the transmittance of the etalon according to Embodiment 1. FIG. 15 to FIG. 18 illustrate a case where the incident angle difference θ between the first light 5 and the second light 9 is set to the angle π/4. FIG. 15 and FIG. 16 illustrate the case where the photodetectors 10 and 11 are separated. FIG. 17 and FIG. 18 illustrate the case where light is collectively received by one photodetector. As compared with the case where the incident angle difference θ is set to the angle π/2, the wavelength locking controllable range can be concentrated.

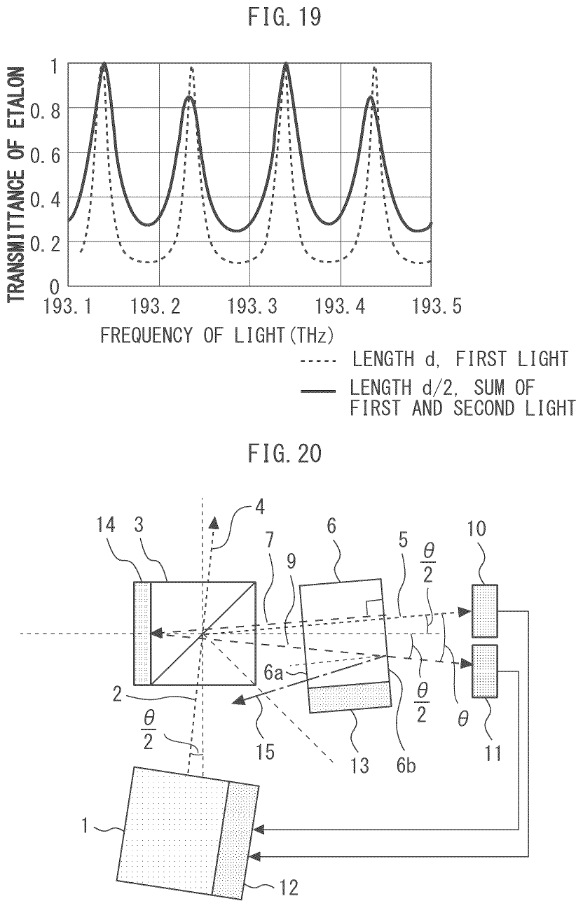

FIG. 19 is a diagram illustrating frequency dependence of transmittance of the etalon according to Embodiment 1. When the wavelength of the light is denoted by λ, a refractive index of the etalon is denoted by n, and a length of the etalon is denoted by d, FSR=λ²/2nd is established. In other words, FSR is inversely proportional to the length d of the etalon. In the present embodiment, when the incident angle difference θ is set to the angle π/2, transmission characteristics of a twofold period can be obtained. Therefore, even when the length of the etalon is reduced to a half, transmission characteristics of the period same as the period in the existing technique can be obtained. Therefore, the length of the etalon can be reduced, and the wavelength locker can be accordingly downsized.

As described above, in the present embodiment, the first light 5 and the second light 9 different in incident angle to the etalon 6 are used. As a result, the range where the gradient of the transmittance of the etalon 6 to wavelength variation of the light is large is widened, and accordingly, the wavelength locking controllable range of the laser light source can be widened. Thus, even when the finesse of the etalon 6 is increased, the controllable range can be secured. When the finesse is increased, the gradient of the transmittance to the wavelength/temperature can be increased. This makes it possible to control the wavelength with high accuracy. Further, the controllable temperature range of the etalon can be widened. Thus, a temperature adjustment amount of the etalon can be reduced, and power consumption can be suppressed. Further, since the second light 9 is obtained by using the reflected light from the etalon 6, the optical system and the etalon can be downsized.

### Embodiment 2

FIG. 20 is a diagram illustrating a wavelength variable light source with a built-in wavelength locker according to Embodiment 2. In the present embodiment, in place of the high reflection mirror 8 according to Embodiment 1, a high reflection film 14 is provided on a side surface of the beam splitter 3. The high reflection film 14 reflects the reflected light 7 at a certain angle to generate the second light 9, and causes the second light 9 to enter the etalon 6 again. The other configuration is similar to the configuration according to Embodiment 1.

When the laser beam 2 having the optical axis tilted by θ/2 is caused to enter the beam splitter 3, the difference of the incident angle to the etalon 6 between the first light 5 and the second light 9 becomes θ. Therefore, the first light 5 and the second light 9 are different in transmission wavelength of the etalon 6 and in clearing temperature of the etalon 6. Therefore, effects similar to the effects by Embodiment 1 can be achieved.

Note that it is conceivable that second reflected light 15 from the etalon 6 reflected by the high reflection film 14 enters the etalon 6 again. Such light has a remaining component of the reflected light 7 and 15, and has a complicated transmission shape. Wavelength locking control based on such light is difficult. Therefore, to prevent the reflected light 15 from becoming third incident light to the etalon 6, outer sizes and arrangement of the beam splitter 3 and the etalon 6 are set. Alternatively, to prevent the third incident light from entering the photodetectors 10 and 11, outer sizes and arrangement of the photodetectors 10 and 11 are adjusted.

### Embodiment 3

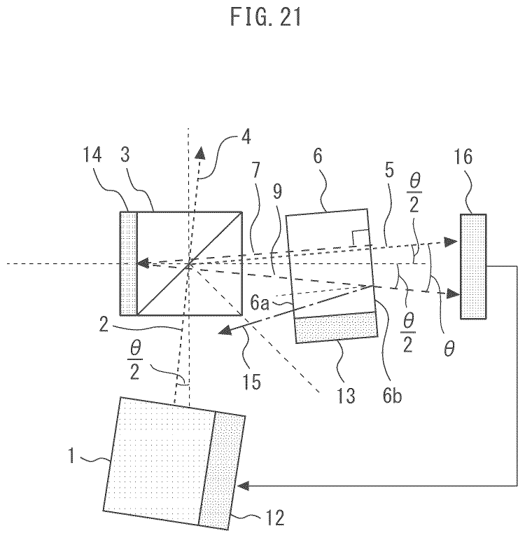

FIG. 21 is a diagram illustrating a wavelength variable light source with a built-in wavelength locker according to Embodiment 3. One large photodetector 16 receives the first light 5 and the second light 9 having passed through the etalon 6. The other configuration is similar to the configuration according to Embodiment 2. Even in this case, effects similar to the effects by Embodiments 1 and 2 can be achieved.

### REFERENCE SIGNS LIST

1 laser light source; 2 laser beam; 3 beam splitter; 5 first light; 6 etalon; 7 reflected light; 8 high reflection mirror (reflector); 9 second light; 10,11,16 photodetector; 12 temperature adjustment unit; 14 high reflection film (reflector)

1. A wavelength locker comprising:
a beam splitter splitting a laser beam to generate first light;
an etalon allowing part of the first light to pass therethrough and reflecting remaining part of the first light by an end surface to generate reflected light;
a reflector reflecting the reflected light to a generate second light and causing the second light to enter the etalon; and
photodetectors respectively receiving the first light and the second light having passed through the etalon,
wherein the first light and the second light are different in incident angle to the etalon and are different in optical path length inside the etalon.

2. The wavelength locker according to claim 1, wherein the reflector is a high reflection mirror reflecting the reflected light at a certain angle to generate the second light and causing the second light to enter the etalon.

3. The wavelength locker according to claim 1, wherein the reflector is a high reflection film provided on a side surface of the beam splitter.

4. The wavelength locker according to claim 3, wherein outer sizes and arrangement of the beam splitter and the etalon are set to prevent part of the second light reflected by the end surface of the etalon from entering the etalon again or from entering the photodetector.

5. The wavelength locker according to claim 1, wherein one of the photodetectors receives the first light and the second light having passed through the etalon.

6. A wavelength variable light source with a built-in wavelength locker comprising:
the wavelength locker according to claim 1;
a laser light source emitting a laser beam; and
a temperature adjustment unit adjusting a temperature of the laser light source based on an output signal of the photodetector and performing control to fix an oscillation wavelength of the laser light source.
